(19) United States
(12) Patent Application Publication
(10) Pub. No.: US 2026/0161848 A1
(43) Pub. Date: Jun. 11, 2026

(54) INFORMATION PROCESSING APPARATUS, INFORMATION PROCESSING METHOD, AND STORAGE MEDIUM

(71) Applicant: NEC Corporation, Tokyo (JP)

(72) Inventors: Yuki NAKAGUCHI, Tokyo (JP); Shumpei Kubosawa, Tokyo (JP)

(73) Assignee: NEC Corporation, Tokyo (JP)

(21) Appl. No.: 19/404,111

(22) Filed: Dec. 1, 2025

(30) Foreign Application Priority Data
Dec. 11, 2024 (JP) 2024-217009

(51) Int. Cl. G06F 30/20

(52) U.S. Cl. CPC G06F 30/20

(57) ABSTRACT

An information processing apparatus of the present disclosure includes a setting unit that sets, in a coordinate space in which a position and time are set as axes, an occupied area representing a space and time occupied by a moving body at a time of movement, and an arrangement unit that arranges the occupied area in the coordinate space in such a way that a plurality of the occupied areas do not overlap each other.

### INCORPORATION OF BASIC APPLICATION

The present invention is based upon and claims the benefit of priority from Japanese patent application No. 2024-217009, filed on December 11, 2024 in Japan, the disclosure of which is incorporated herein in its entirety by reference.

### TECHNICAL FIELD

The present disclosure relates to an information processing apparatus, an information processing method, and a storage medium.

### BACKGROUND ART

Patent Literature 1 describes a method for creating a train diagram. Specifically, in Patent Literature 1, it is checked for a single-track section whether inter-station meet occurs, at the time of creating a train path in the train diagram, and in a case where inter-station meet occurs, the train path in the train diagram is corrected in such a way as to evacuate a train to a station where evacuation is allowed.

Patent Literature 1: Japanese Unexamined Patent Application Publication No. JP H10- 181604 A

### SUMMARY

However, in Patent Literature 1 described above, there arises a difficulty that creation of the train diagram for the single-track section requires time and effort in checking and correction, and it takes time to create the train diagram. A similar difficulty arises not only in a diagram for train but also in a case of creating a diagram for a moving body such as an airplane that involves occupation of time and space.

Therefore, an object of the present disclosure is to solve the problem described above, that is, that it takes time to create a diagram for a moving body.

An information processing apparatus according to an aspect of the present disclosure has a configuration including a setting unit that sets, in a coordinate space in which a position and time are set as axes, an occupied area representing a space and time occupied by a moving body at a time of movement, and an arrangement unit that arranges the occupied area in the coordinate space in such a way that a plurality of the occupied areas do not overlap each other. An information processing method according to an aspect of the present disclosure has a configuration including setting, in a coordinate space in which a position and time are set as axes, an occupied area representing a space and time occupied by a moving body at a time of movement, and arranging the occupied area in the coordinate space in such a way that a plurality of the occupied areas do not overlap each other. A program according to an aspect of the present disclosure has a configuration for causing an information processing apparatus to execute a process including setting, in a coordinate space in which a position and time are set as axes, an occupied area representing a space and time occupied by a moving body at a time of movement, and arranging the occupied area in the coordinate space in such a way that a plurality of the occupied areas do not overlap each other.

With the above configuration, the present disclosure can shorten the time required to create a diagram for a moving body.

### BRIEF DESCRIPTION OF THE DRAWINGS

FIG. 1 is a block diagram illustrating an example of a configuration of an information processing apparatus according to the present disclosure;

FIG. 2 is a flowchart illustrating an example of a processing operation of the information processing apparatus according to the present disclosure;

FIG. 3 is a diagram illustrating an example of a state of processing of the information processing apparatus according to the present disclosure;

FIG. 4 is a diagram illustrating an example of a state of processing of the information processing apparatus according to the present disclosure;

FIG. 5 is a diagram illustrating an example of a state of processing of the information processing apparatus according to the present disclosure;

FIG. 6 is a diagram illustrating an example of a state of processing of the information processing apparatus according to the present disclosure;

FIG. 7 is a diagram illustrating an example of a state of processing of the information processing apparatus according to the present disclosure;

FIG. 8 is a diagram illustrating an example of a state of processing of the information processing apparatus according to the present disclosure;

FIG. 9 is a block diagram illustrating an example of a hardware configuration of the information processing apparatus according to the present disclosure; and

FIG. 10 is a block diagram illustrating an example of a configuration of the information processing apparatus according to the present disclosure.

### EXAMPLE EMBODIMENT

### <First Example Embodiment>

A first example embodiment of the present disclosure will be described with reference to the drawings. The drawings may be related to any example embodiment.

In one example, an information processing apparatus 10 of the present disclosure is used to create a diagram for a moving body. In the present example embodiment, a case where the moving body is a train will be exemplified, and in particular, a train diagram will be created in such a way that overlapping of trains will not arise in a section in which occupation of a space and time by a train can arise, such as a single-track section.

However, the present disclosure is not limited to the case where the moving body for which a diagram is to be created is a train and can be applied to a case where a diagram for any moving body such as an aircraft or a ship as well as an artificial satellite or a drone is created. For example, in a case where the moving body is an aircraft, an occupied section in time and space is assumed as a predetermined area above an airport or a runway during predetermined time, and it is also applicable to creating a diagram in such a way that overlapping of aircraft will not arise in such an occupied section in time and space.

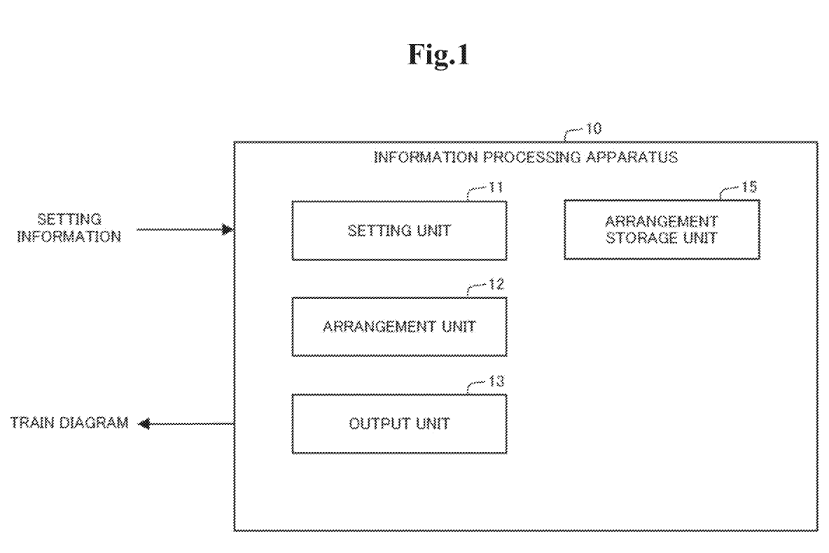

Hereinafter, a configuration and an operation of the information processing apparatus 10 according to the present example embodiment will be described. The information processing apparatus 10 may be a single or a plurality of information processing apparatuses including an arithmetic device and a storage device. Then, as illustrated in FIG. 1, the information processing apparatus 10 includes a setting unit 11, an arrangement unit 12, and an output unit 13. Each of functions of the setting unit 11, the arrangement unit 12, and the output unit 13 can be achieved by the arithmetic device executing a program for achieving each function stored in the storage device. The information processing apparatus 10 also includes an arrangement storage unit 15 formed by a storage device.

First, the setting unit 11 acquires setting information for creating a train diagram. Here, the train diagram to be created is assumed to be information on a timetable line chart (diagram) expressing a service plan for the train. The setting information includes information on a position and a section where the train travels, such as a station and a distance between stations, and information on time for which a train diagram is to be created. The section where the train travels is assumed as an occupied section such as a single-track section. Meanwhile, it is assumed that the single-track section is between stations and the station is in a double-track section and is a non-occupied section.

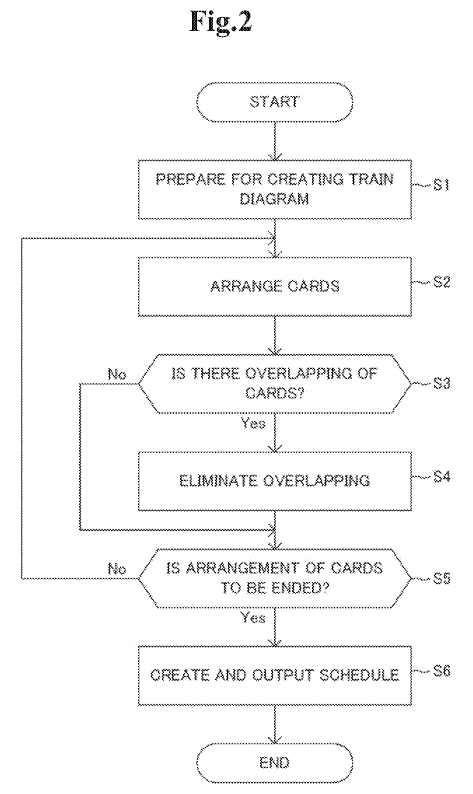

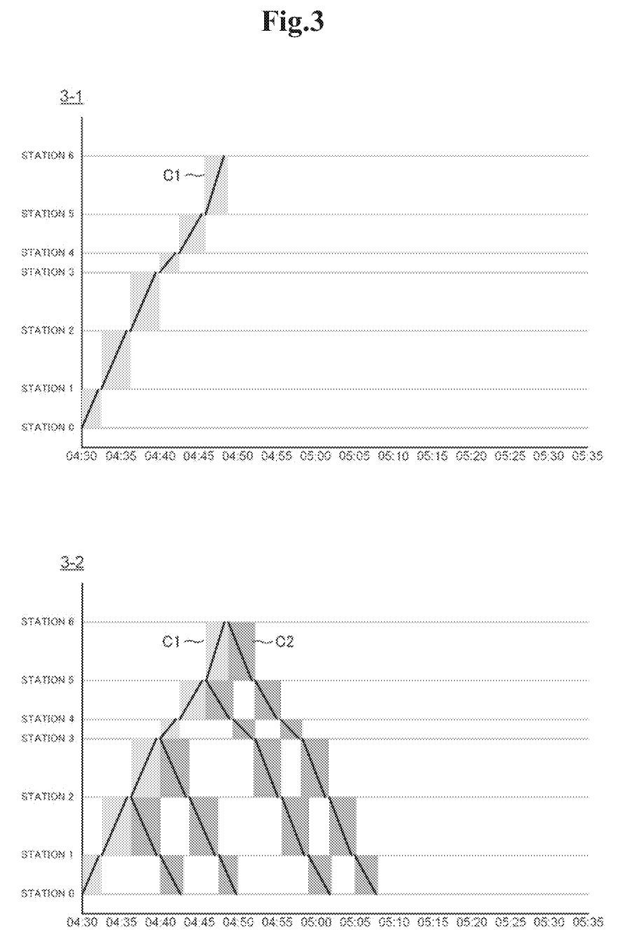

Then, the setting unit 11 prepares for creating a train diagram, based on the acquired setting information (step S1 in FIG. 2). Specifically, as illustrated in FIG. 3, for example, the setting unit 11 generates a coordinate space of a train diagram in which time (time of day) is set on a horizontal axis and a station (position) is set on a vertical axis. The setting unit 11 also sets a card that can be arranged in the coordinate space of the train diagram and is relevant to a train that travels between stations. The card is a rectangular figure graphically representing the position and time at which the train is scheduled to move and includes a train path represented by a diagonal line inside the rectangular figure relevant to the movement of the train. In one example, as illustrated in FIG. 3, the card can be arranged between stations and is formed in such a way that a horizontal width represents moving time and a vertical width represents a zone between stations, where the train path located diagonally is formed in such a way as to extend from coordinates of (departure time, departure station) to coordinates of (arrival time, arrival station). In this manner, the vertical width of the card is relevant to a zone between stations that is a single-track section where the train travels, and the horizontal width is relevant to time during which the train travels between the stations. Therefore, the area of the card represents an area in which the relevant train occupies a zone between stations that is a single-track section and represents an occupied area in the coordinate space. That is, another train will not be allowed to enter the real space during a timeslot corresponding to an area in which the card is arranged in the coordinate space.

The arrangement unit 12 arranges a card relevant to a train in the coordinate space of the train diagram (step S2 in FIG. 2). Specifically, the arrangement unit 12 first arranges a card C1 relevant to a first train (first moving body) as illustrated in FIG. 3 (3-1). At this time, one card C1 is arranged at each zone between stations. The example in FIG. 3 (3-1) illustrates a situation of the cards C1 arranged for a train that departs from a “station 0” at the “time 04:30” and arrives at a “station 6” at the “time 04:48”.

Subsequently, as illustrated in FIG. 3 (3-2), the arrangement unit 12 arranges a card C2 relevant to another train (second moving body) that passes the first train coming from an opposite direction at a station. Specifically, the card C2 is arranged in such a way that the another train departs in an opposite direction at the station and time of the first train's arrival and departure. An inter-card point between the cards C1 of the first train, that is, each point between vertexes of the cards C1 is located at an arrival-departure station, and the stations are non-occupied areas by the first train because the stations are in a double-track section. Therefore, at an inter-card point, that is, at a station, the another train is also allowed to be stopped in a case where the first train is stopped, and the trains can pass each other in such a way as to be able to depart in opposite directions. Then, when the cards C2 of the another train are arranged, a plurality of stations is uniformly selected from the stations where the first train arrives and departs, and the cards C2 are arranged in such a way that the another train departs from each of the selected plurality of stations. In this manner, the cards C2 relevant to the another train that passes the first train coming from an opposite direction at a station are arranged in the coordinate space of the train diagram in a leveled manner. The example in FIG. 3 (3-2) illustrates a situation of the cards C2 arranged for the another train that passes the first train coming from an opposite direction and departs to the opposite direction at a time when the first train arrives and departs from each of a “station 2”, a “station 3”, a “station 5”, and the “station 6”, and four series of the cards C2 of the another train are separately arranged.

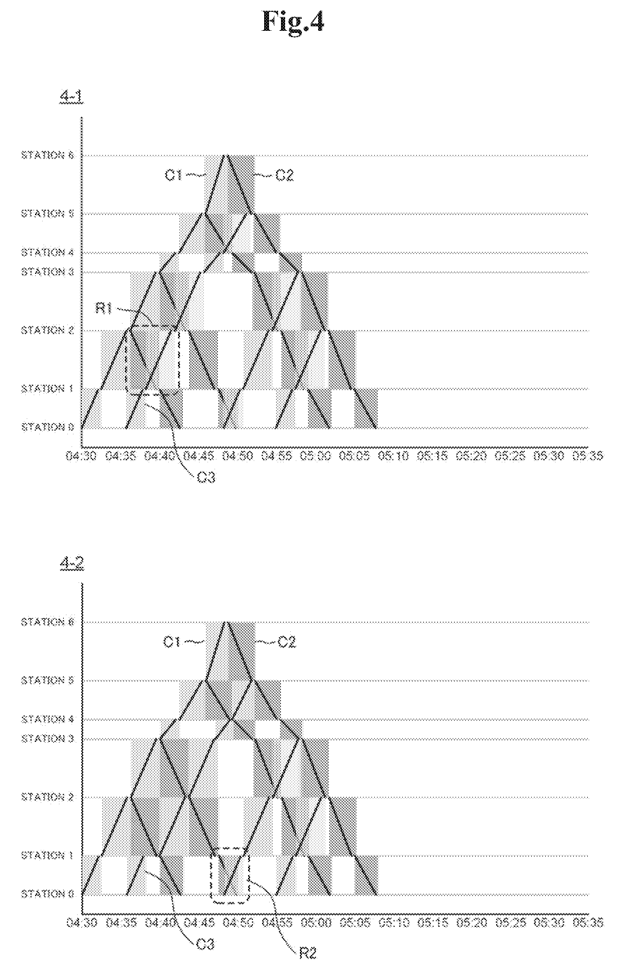

Subsequently, as illustrated in FIG. 4 (4-1), the arrangement unit 12 further arranges a card C3 relevant to still another train (third moving body), based on movement statuses of the first train and the another train, that is, the arrangement of the cards C1 of the first train and the cards C2 of the another train. For example, the arrangement unit 12 arranges the card C3 relevant to the still another train in such a way as to depart in the same direction as the first train at a predetermined time interval from the time of departure of the first train. At this time, furthermore, the cards C3 are arranged in such a way that the still another train passes the another train coming from an opposite direction at some stations and times at which the another train (cards C2) arrives and departs. The arrangement unit 12 further arranges the cards C3 relevant to the still another train at a predetermined time interval similarly to the description above. For example, the arrangement unit 12 arranges a plurality of the cards C3 of the still another train in a patterned manner such as at a certain interval from the first train or by making arrivals at and departures from each station at a regular time of day. The example in FIG. 4 (4-1) illustrates a situation of the cards C3 arranged for the still another train that departs from the “station 0” at the “time 04:36” and passes the another train coming from an opposite direction at the “station 5” at the “time 04:52”, the cards C3 arranged for the still another train that departs from the “station 0” at the “time 04:48” and passes the another train coming from an opposite direction at the ”station 3” at the “time 04:57”, and the cards C3 arranged for the still another train that departs from the “station 0” at the “time 04:55" and passes the another train coming from an opposite direction at the “station 2” at the “time 05:02”, and three series of the cards C3 of the still another train are separately arranged. Here, it is assumed that cards of the still another train are arranged only in some sections on a departure station side.

Subsequently, when arranging the cards C3 of the still another train as described above, in a case where the cards C3 of the still another train overlap the other cards C1 and C2 (Yes in step S3 in FIG. 2), the arrangement unit 12 moves the cards in the coordinate space in such a way that the cards do not overlap each other (step S4 in FIG. 2). At this time, in a case where overlapping of the cards occurs at a plurality of places, the arrangement unit 12 sequentially moves cards from a place where the overlapping time is earliest in such a way as to eliminate the overlapping of cards. Furthermore, at this time, the arrangement unit 12 moves one of overlapping cards towards a later time to eliminate the overlapping. The arrangement unit 12 is not limited to moving a card and may change a card by, for example, shortening the horizontal width of the card. That is, since the horizontal width of the card corresponds to the time during which the train moves between stations, the moving time between stations may be changed by changing the speed of the train within a speed limit. In this manner, the arrangement unit 12 sets a card in the coordinate space in such a way as to eliminate the overlapping of cards, by, for example, moving the arrangement of one of overlapping cards or changing the horizontal width of a card.

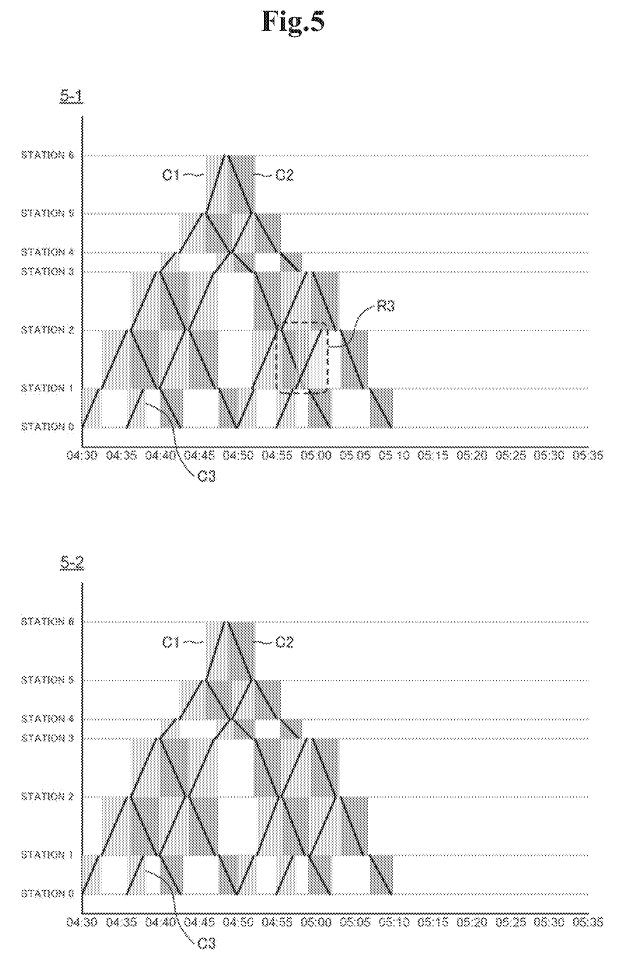

Here, in the example in FIG. 4 (4-1), overlapping of cards occurs at a plurality of places. At this time, the card C3 of the still another train that departs from the “station 0” at the time “04:36” overlaps the card C2 of the another train at the place denoted by the reference sign R1, and this place has the earliest time. Thus, the overlapping between the cards is eliminated by shifting the card C3 of the still another train to a later time. Accordingly, the other cards C3 relevant to the same still another train are shifted to later times in a chain manner, and in a case where overlapping between cards further arises due to this shifting, the overlapping is eliminated similarly to the description above. As a result, as illustrated in FIG. 4 (4-2), overlapping of the cards C3 of the train that departs from the “station 0” at the time “04:36” is eliminated. Subsequently, as indicated by the reference sign R2 in FIG. 4 (4-2), since overlapping between cards arises at a still later time, a card of the train relevant to the overlapping cards is moved to a later time similarly to the description above, and the overlapping between the cards is eliminated as illustrated in FIG. 5 (5-1). Subsequently, as indicated by the reference sign R3 in FIG. 5 (5-1), since overlapping between cards arises at a still later time, a card of the train relevant to the overlapping cards is moved to a later time similarly to the description above, and the overlapping between the cards is eliminated as illustrated in FIG. 5 (5-2).

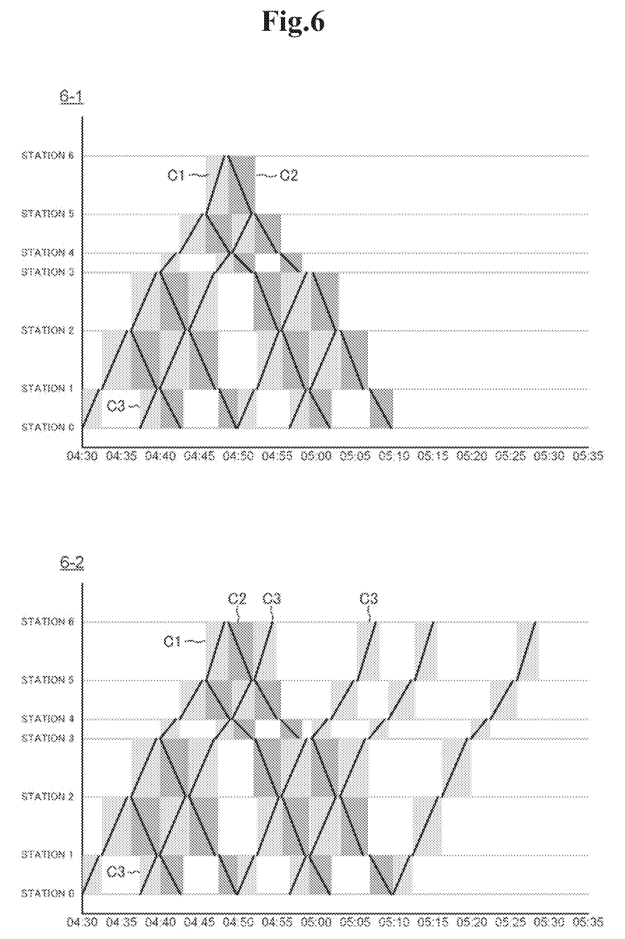

The arrangement unit 12 may move a card as appropriate in order to eliminate unnecessary stop time of each train at each station when eliminating overlapping between the cards described above. For example, as illustrated in FIG. 5 (5-2), in the train that departs from the “station 0” at the time “04:36”, unnecessary stop time is produced at the next “station 1”. Therefore, the relevant card C3 is moved as illustrated in FIG. 6 (6-1) in such a way that the stop time of that train at the “station 1” is shortened. In the example described above, overlapping of cards is eliminated by setting a card to be moved, but overlapping of cards may be eliminated by setting the horizontal width of a card to be changed.

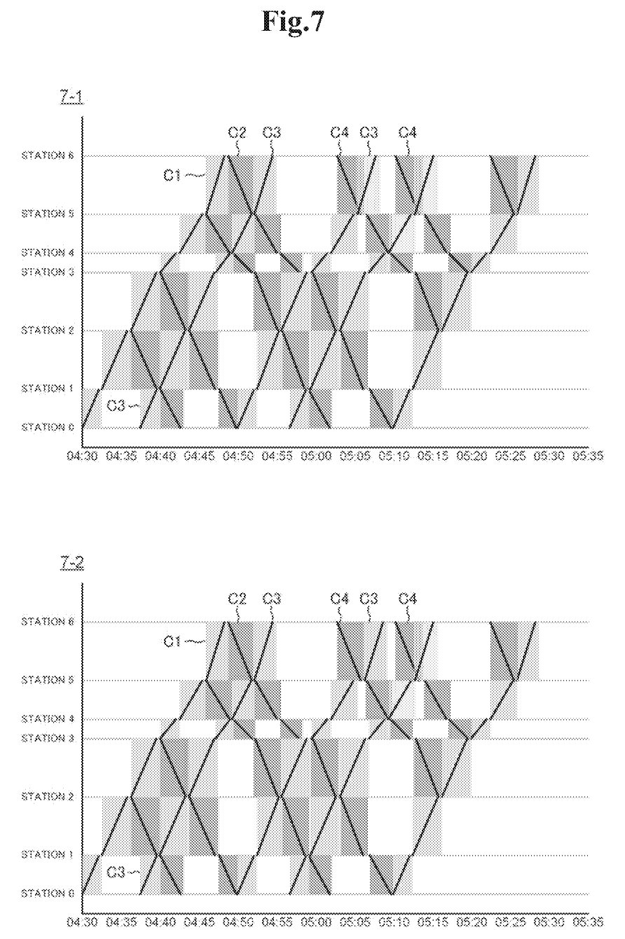

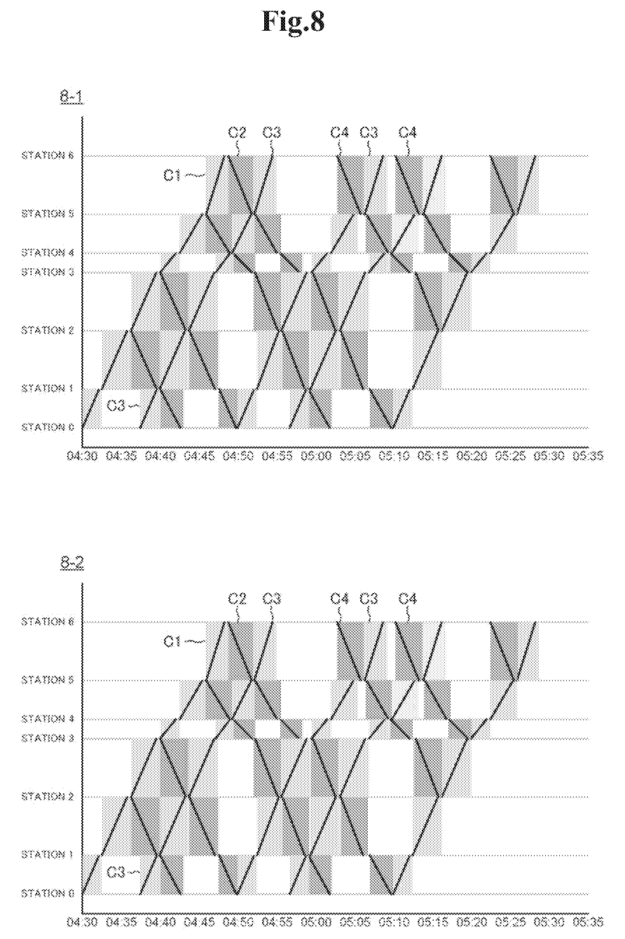

Subsequently, since the train diagram has not been completed and the arrangement of the cards has not been finished (No in step S5 in FIG. 2), the arrangement unit 12 further arranges the cards C3 of the still another train in a following section. For example, for the cards C3 of the still another train, as illustrated in FIG. 6 (6-2), the cards C3 are added and further arranged in a following section from a passing place with the card C2 of the another train. Then, similarly to the cards C2 of the another train described above, the arrangement unit 12 arranges a card C4 relevant to yet another train that passes the still another train coming from an opposite direction at a station as illustrated in FIG. 7 (7-1). At this time, in a case where overlapping between cards occurs due to the arrangement of the cards C4, the arrangement unit 12 sequentially moves a card in a later time direction from the card with the earliest time to eliminate the overlapping, similarly to the description above. For example, overlapping of cards is sequentially eliminated from the situation illustrated in FIG. 7 (7-1) to FIGS. 7 (7-2) and 8 (8-1). Thereafter, in a case where unnecessary stop time of each train at each station arises due to the elimination of overlapping of cards, the arrangement unit 12 moves the relevant card as illustrated in FIG. 8 (8-2) in such a way as to shorten the stop time. The arrangement unit 12 always stores the arrangement of cards in the coordinate space of the train diagram in the arrangement storage unit 15 when arranging or moving a card as described above.

Then, when the desired train diagram is completed and the arrangement of the cards is finished (Yes in step S5 in FIG. 2), the output unit 13 creates and outputs a train schedule, based on the final arrangement of the cards in the train diagram (step S6 in FIG. 2). For example, the output unit 13 extracts the arrival time and the departure time of each train at each station from the arrangement of the cards and the train paths inside the cards and creates and outputs the extracted arrival time and departure time, as data of a train schedule.

As described above, by eliminating overlapping of cards relevant to trains, a train diagram can be created in which overlapping of the trains in a section in which occupation of a space and time can arise, such as a single-track section, is eliminated. As a result, time and effort in checking and correcting the train diagram can be suppressed at the time of creation, and the creation time for the train diagram can be shortened.

In the present disclosure, the moving body for which a diagram is to be created is not limited to a train as described earlier and may be any moving body such as a ship or an aircraft. In this case, the above-described coordinate space and cards have different shapes depending on the moving body. In one example, in a case where the moving body is a ship, the coordinate space is configured as a three-dimensional time-space with a two-dimensional space + one-dimensional time, and the card can be replaced with a figure such as a rectangular parallelepiped. In one example, in a case where the moving body is an aircraft, the coordinate space is configured as a four-dimensional time-space with a three-dimensional space + one-dimensional time, and the card can be replaced with a figure having a four-dimensional hypervolume.

### <Second Example Embodiment>

Next, a second example embodiment of the present disclosure will be described with reference to the drawings. In the present example embodiment, an outline of the information processing apparatus and the like described in the above example embodiment will be illustrated. The drawings may relate to any example embodiment.

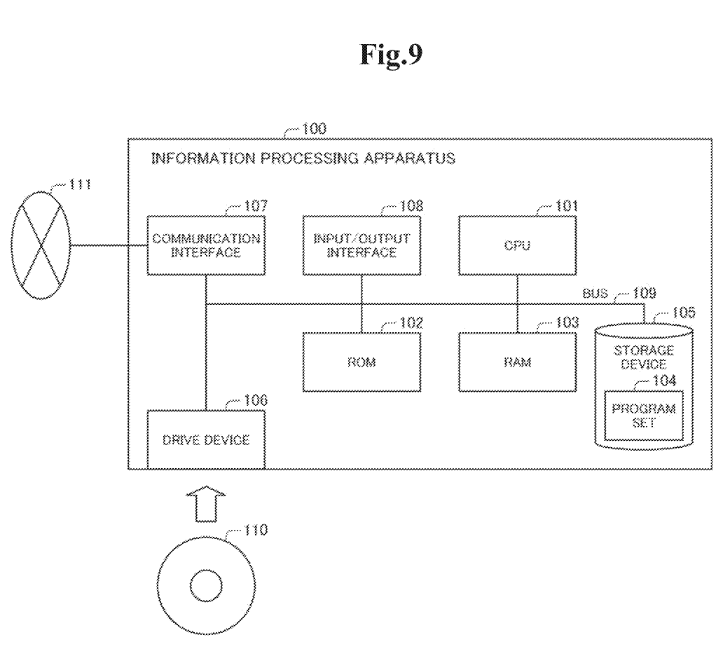

First, a hardware configuration of an information processing apparatus 100 according to the present disclosure will be described. The information processing apparatus 100 is constituted by a general information processing apparatus and, in one example, is equipped with the hardware configuration as follows, as illustrated in FIG. 9.

Central processing unit (CPU) 101 (arithmetic device)

Read only memory (ROM) 102 (storage device)

Random access memory (RAM) 103 (storage device)

Program set 104 to be loaded into RAM 103

Storage device 105 storing program set 104

Drive device 106 for performing reading and writing on storage medium 110 outside information processing apparatus

Communication interface 107 connected to communication network 111 outside information processing apparatus

Input/output interface 108 for inputting and outputting data

Bus 109 for connecting each component

FIG. 9 illustrates an example of the hardware configuration of the information processing apparatus that is the information processing apparatus 100, and the hardware configuration of the information processing apparatus is not limited to the above case. For example, the information processing apparatus may be constituted by a part of the above configuration such as not including the drive device 106. Instead of the CPU described above, the information processing apparatus can use a graphic processing unit (GPU), a digital signal processor (DSP), a micro processing unit (MPU), a floating point number processing unit (FPU), a physics processing unit (PPU), a tensor processing unit (TPU), a quantum processor, a microcontroller, a combination of these, or the like.

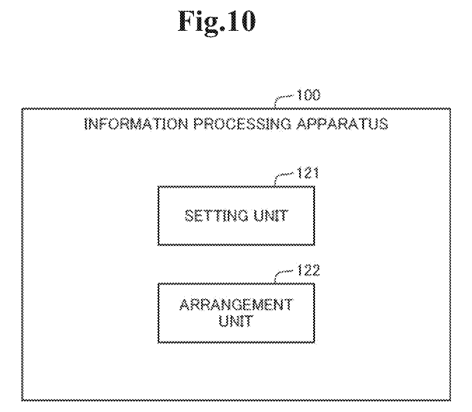

Then, a setting unit 121 and an arrangement unit 122 illustrated in FIG. 10 can be constructed and equipped in the information processing apparatus 100 by the CPU 101 acquiring the program set 104 and executing the acquired program set 104 by itself. The program set 104 is stored, for example, in the storage device 105 or the ROM 102 in advance, and the CPU 101 loads and executes the stored program set 104 on the RAM 103, as necessary. The program set 104 may be supplied to the CPU 101 via the communication network 111, or the drive device 106 may read the programs stored in the storage medium 110 in advance and supply the read programs to the CPU 101. However, the setting unit 121 and the arrangement unit 122 described above may be constructed by a dedicated electronic circuit for achieving these means.

The setting unit 121 described above sets, in a coordinate space in which a position and time are set as axes, a movement figure representing a position and time at which the moving body is scheduled to move, with a figure. The arrangement unit 122 described above arranges a plurality of the movement figures in the coordinate space in such a way that the movement figures do not overlap each other.

With the above configuration, the present disclosure arranges a plurality of movement figures in the coordinate space in such a way as not to overlap each other, whereby a diagram for the moving body can be created in such a way that moving bodies relevant to the movement figures do not overlap in an occupied space. As a result, the time required to create a diagram for the moving body can be shortened.

At least one or more of the functions of the setting unit 121 and the arrangement unit 122 described above may be executed by an information processing apparatus installed and connected at any place on a network, that is, may be executed on so-called cloud computing.

The programs described above can be stored using various types of non-transitory computer readable media and supplied to a computer. The non-transitory computer readable media include various types of tangible recording media (tangible storage media). Examples of the non-transitory computer readable medium include a magnetic recording medium (for example, a flexible disk, a magnetic tape, or a hard disk drive), an optical magnetic recording medium (for example, a magneto-optical disc), a compact disc read only memory (CD-ROM), a compact disc recordable (CD-R), a compact disc rewritable (CD-R/W), and a semiconductor memory (for example, a mask ROM, a programmable ROM (PROM), an erasable PROM (EPROM), a flash ROM, or a random access memory (RAM)). The programs may also be supplied to the computer by various types of transitory computer readable media. Examples of the transitory computer readable media include electrical signals, optical signals, and electromagnetic waves. The transitory computer readable media can supply the programs to the computer via a wired communication line such as an electric wire and an optical fiber, or a wireless communication line.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment described above can be appropriately combined with other example embodiments.

### <Supplementary Note>

Some or all of the above example embodiments may be described as in the following Supplementary Notes. Hereinafter, an outline of configurations of the information processing apparatus, the information processing method, and the program according to the present disclosure will be described. However, the present disclosure is not limited to the configurations described in the following Supplementary Notes.

Some or all of the configurations described in the Supplementary Notes 2 to 8 dependent on the Supplementary Note 1 described below and the functions according to those configurations can also be dependent on the other Supplementary Notes 9 and 10 by a dependency relationship similar to that of the Supplementary Notes 2 to 8. Moreover, some or all of the configurations described as the Supplementary Notes and the functions according to those configurations can be similarly dependent on not only Supplementary Notes 1, 9, and 10, but also various pieces of similar hardware and software, and various types of recording means that record the software, or systems without departing from the above-described example embodiments.

### (Supplementary Note 1)

An information processing apparatus including: a setting unit that sets, in a coordinate space in which a position and time are set as axes, an occupied area representing a space and time occupied by a moving body at a time of movement; and an arrangement unit that arranges the occupied area in the coordinate space in such a way that a plurality of the occupied areas do not overlap each other.

### (Supplementary Note 2)

The information processing apparatus according to Supplementary Note 1, in which the arrangement unit arranges, in the coordinate space, the occupied area of a second moving body that is a second one of the moving body, in such a way that the second moving body passes a first moving body that is a first one of the moving body, at a position and a time between the occupied areas of the first moving body in the coordinate space.

### (Supplementary Note 3)

The information processing apparatus according to Supplementary Note 2, in which the arrangement unit separately arranges the occupied areas of a plurality of the second moving bodies in the coordinate space in a leveled manner in such a way that the plurality of the second moving bodies each passes the first moving body at a plurality of positions and times relevant to points between a plurality of the occupied areas of the first moving body in the coordinate space.

### (Supplementary Note 4)

The information processing apparatus according to Supplementary Note 2, in which the arrangement unit arranges the occupied area of a third moving body that is a third one of the moving body, in the coordinate space, based on an arrangement status of the occupied areas of each of the first moving body and the second moving body in the coordinate space, and in a case where the occupied area of the third moving body overlaps another one of the occupied areas in the coordinate space, sets the overlapping occupied areas in the coordinate space in such a way that the occupied areas do not overlap each other.

### (Supplementary Note 5)

The information processing apparatus according to Supplementary Note 4, in which the arrangement unit sets the overlapping occupied areas in the coordinate space sequentially from the occupied area of which overlapping time is earliest in such a way that the occupied areas do not overlap.

### (Supplementary Note 6)

The information processing apparatus according to Supplementary Note 5, in which the arrangement unit sets an overlapping one of the occupied areas in a later time direction in the coordinate space in such a way as not to overlap with another one of the occupied areas.

### (Supplementary Note 7)

The information processing apparatus according to Supplementary Note 1, in which the coordinate space is a diagram in which the position is set on a vertical axis and the time is set on a horizontal axis, and the occupied area is formed with a rectangular figure having a moving body path as a diagonal line.

### (Supplementary Note 8)

The information processing apparatus according to Supplementary Note 1, further including an output unit that outputs relevance information on the position and the time of the moving body, based on an arrangement of the occupied areas in the coordinate space.

### (Supplementary Note 9)

An information processing method including: setting, in a coordinate space in which a position and time are set as axes, an occupied area representing a space and time occupied by a moving body at a time of movement; and arranging the occupied area in the coordinate space in such a way that a plurality of the occupied areas do not overlap each other.

### Supplementary Note 10

A program for causing an information processing apparatus to execute a process including: setting, in a coordinate space in which a position and time are set as axes, an occupied area representing a space and time occupied by a moving body at a time of movement; and arranging the occupied area in the coordinate space in such a way that a plurality of the occupied areas do not overlap each other.

1. An information processing apparatus comprising:
at least one memory configured to store processing instructions; and
at least one processor configured to execute the processing instructions to:
set, in a coordinate space in which a position and time are set as axes, an occupied area representing a space and time occupied by a moving body at a time of movement; and
arrange the occupied area in the coordinate space in such a way that a plurality of the occupied areas do not overlap each other.

2. The information processing apparatus
according to claim 1, wherein the at least one processor is configured to execute the processing instructions to
arrange, in the coordinate space, the occupied area of a second moving body that is a second one of the moving body, in such a way that the second moving body passes a first moving body that is a first one of the moving body, at a position and a time between the occupied areas of the first moving body in the coordinate space.

3. The information processing apparatus
according to claim 2, wherein the at least one processor is configured to execute the processing instructions to
separately arrange the occupied areas of a plurality of the second moving bodies in the coordinate space in a leveled manner in such a way that the plurality of the second moving bodies each passes the first moving body at a plurality of positions and times relevant to points between a plurality of the occupied areas of the first moving body in the coordinate space.

4. The information processing apparatus
according to claim 2, wherein the at least one processor is configured to execute the processing instructions to
arrange the occupied area of a third moving body that is a third one of the moving body, in the coordinate space, based on an arrangement status of the occupied areas of each of the first moving body and the second moving body in the coordinate space, and in a case where the occupied area of the third moving body overlaps another one of the occupied areas in the coordinate space, sets the overlapping occupied areas in the coordinate space in such a way that the occupied areas do not overlap each other.

5. The information processing apparatus
according to claim 4, wherein the at least one processor is configured to execute the processing instructions to
set the overlapping occupied areas in the coordinate space sequentially from the occupied area of which overlapping time is earliest in such a way that the occupied areas do not overlap.

6. The information processing apparatus
according to claim 5, wherein the at least one processor is configured to execute the processing instructions to
set an overlapping one of the occupied areas in a later time direction in the coordinate space in such a way as not to overlap with another one of the occupied areas.

7. The information processing apparatus
according to claim 1, wherein
the coordinate space is a diagram in which the position is set on a vertical axis and the time is set on a horizontal axis, and
the occupied area is formed with a rectangular figure having a moving body path as a diagonal line.

8. The information processing apparatus
according to claim 1, wherein the at least one processor is configured to execute the processing instructions to
output relevance information on the position and the time of the moving body, based on an arrangement of the occupied areas in the coordinate space.

9. An information processing method comprising:
setting, in a coordinate space in which a position and time are set as axes, an occupied area representing a space and time occupied by a moving body at a time of movement; and
arranging the occupied area in the coordinate space in such a way that a plurality of the occupied areas do not overlap each other.

10. The information processing method
according to claim 9, further comprising
arranging, in the coordinate space, the occupied area of a second moving body that is a second one of the moving body, in such a way that the second moving body passes a first moving body that is a first one of the moving body, at a position and a time between the occupied areas of the first moving body in the coordinate space.

11. The information processing method
according to claim 10, further comprising
separately arranging the occupied areas of a plurality of the second moving bodies in the coordinate space in a leveled manner in such a way that the plurality of the second moving bodies each passes the first moving body at a plurality of positions and times relevant to points between a plurality of the occupied areas of the first moving body in the coordinate space.

12. The information processing method
according to claim 10, further comprising
arranging the occupied area of a third moving body that is a third one of the moving body, in the coordinate space, based on an arrangement status of the occupied areas of each of the first moving body and the second moving body in the coordinate space, and in a case where the occupied area of the third moving body overlaps another one of the occupied areas in the coordinate space, setting the overlapping occupied areas in the coordinate space in such a way that the occupied areas do not overlap each other.

13. The information processing method
according to claim 9, wherein
the coordinate space is a diagram in which the position is set on a vertical axis and the time is set on a horizontal axis, and
the occupied area is formed with a rectangular figure having a moving body path as a diagonal line.

14. The information processing method
according to claim 9, further comprising
outputting relevance information on the position and the time of the moving body, based on an arrangement of the occupied areas in the coordinate space.

15. A computer readable storage medium storing a program for causing
an information processing apparatus to execute a process comprising:
setting, in a coordinate space in which a position and time are set as axes, an occupied area representing a space and time occupied by a moving body at a time of movement; and
arranging the occupied area in the coordinate space in such a way that a plurality of the occupied areas do not overlap each other.
